(19) United States
(12) Patent Application Publication
(10) Pub. No.: US 2001/0053585 A1
(43) Pub. Date: Dec. 20, 2001

(54) Cleaning process for substrate surface

(75) Inventors: Satoshi Kikuchi, Okayama-shi (JP); Kousaku Matsuno, Okayama-shi (JP); Haruru Watatsu, Okayama-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: m-FSI LTD., Chiyoda-ku (JP)

(21) Appl. No.: 09/846,255

(22) Filed: May 2, 2001

(30) Foreign Application Priority Data
May 9, 2000 (JP) 2000-135881

(51) Int. Cl. H01L 21/322

(52) U.S. Cl. 438/477

(57) ABSTRACT

Disclosed herein is a cleaning process for a substrate surface on which a high-density film and a low-density film lower in density than the high-density film are carried in combination. According to the cleaning process, a mixed gas of anhydrous hydrogen fluoride gas and a heated inert gas is brought into contact with the substrate surface such that at least a portion of the low-density film is removed without impairing the high-density film beyond a tolerance. The substrate is, for example, a semiconductor substrate.

### BACKGROUND OF THE INVENTION

a) Field of the Invention

This invention relates to a cleaning process for a substrate surface, which upon forming, for example, an element structure on a substrate for the fabrication of a semiconductor device or the like, can selectively remove an unnecessary oxide film formed on the substrate and impurities adhered on an outermost surface of the substrate without impairing a thermal film and the element structure intentionally formed on the substrate.

b) Description of the Related Art

A microcircuit provided with individual elements of sources, drains and gates may use a SiO₂ film as an insulating material for gate regions in some instances as typified by a MOS (metal oxide-silicon) semiconductor device which uses high-purity silicon as a substrate. In the course of formation of such a thin film which may be called a “gate oxide film”, it is particularly important to form the gate oxide film with a uniform, homogeneous material (SiO₂) of high purity. This step is one of important steps which govern the yield of products especially upon formation of fine element structures.

In recent years, there is a move toward using a lower temperature for the formation of gate regions. It is the current practice that, when a silicon substrate is employed, for example, a high-quality SiO₂ film as a gate oxide film is formed by thermally oxidizing metal silicon at a temperature of from 800° C. to 1,100° C. or so under an atmosphere which contains nitrogen and a small amount of oxygen. Upon formation of such gate regions, it is important to form a uniform, homogeneous film as described above. This requires an extremely clean substrate surface, from which deleterious or detrimental causes unnecessary for element structures have been removed, including impurities composed of metals or organic substances as principal components, fine particles suspended or floating in the production environment, and oxide films unintentionally formed on a silicon substrate surface (natural oxide film).

Cleaning treatment is therefore always applied to a substrate surface before formation of gate regions. For the cleaning treatment, various chemical solutions of different functions are used to selectively remove metal impurities, organic substances, fine air-borne particles, and particles formed in the course of formation of elements (hereinafter collectively called “particles”, including particles generally occurring no matter whether they are produced by machine or by man) as well as unnecessary oxide films formed as a result of unintentional oxidation of the substrate itself with an oxidative gas, such as oxygen, contained in the fabrication atmosphere. Wet cleaning treatment (hereinafter called “wet treatment”) is conducted by combining these chemical solutions depending on the objective of the cleaning.

When wet treatment is conducted, however, thick chemical solutions of high temperature are used in large amounts to remove impurities on the outermost surface of a substrate. To rinse the chemical solutions after the treatment, a great deal of water is needed, developing a problem of waste water treatment. There is another problem in that for fine element structures in an electric circuit, the sizes of which are still progressively shrinking year after year, the above-described wet treatment cannot make the various chemical solutions fully penetrate the fine element structures due to limited wettability and can hardly achieve sufficient cleaning treatment.

There is also a move toward reducing the size of fine capacitors—which are formed to store electrical charges, for example, in a semiconductor device—keeping in step with shrinkage in the size of the device itself. Unless the material of the capacitors is changed to one having very large electric capacitance, the above-described reduction in size, in other words, means that the desired electric capacitance can be hardly retained. With a view to overcoming this difficulty and retaining the desired electric capacitance, it is practiced to increase the surface area of each capacitor by fabricating a device in such a way that an intricate structure, for example, a cylindrical structure, a structure provided with a number of fins, or a structure provided with a deep groove is formed on a substrate.

When forming such an intricate structure, a special technique is required to selectively remove unnecessary regions (low-density films) such as natural oxide films and particles without impairing regions required for the construction of the device. If wet treatment is applied to the substrate to remove the low-density films, a problem arises as will be described hereinafter. It is known that in wet treatment, the treatment is conducted with a chemical solution which contains hydrofluoric acid. In general, however, wet treatment requires such treatment as dipping of a substrate in its entirety in a chemical solution or spraying of the chemical solution onto the whole substrate. A problem, therefore, arises in that irrespective of the concentration, component or the like of the chemical solution, intentionally formed high-density films (i.e., intentionally formed element structures such as thermal oxide films) and unintentionally formed, unnecessary films (low-density films)—such as oxide films formed by natural oxidization and oxide films formed with the chemical solution—are treated equally without distinction. Wet treatment is, therefore, not suited especially for the treatment of a substrate having element structures which require selectivity in cleaning as described above.

On the other hand, dry cleaning treatment which features removal of low-density films on a substrate in a vapor phase (hereinafter called “dry treatment”) is also known. According to such dry treatment, intended cleaning can be readily achieved even for fine element structures which are hardly penetrable by chemical solutions employed in wet treatment. Moreover, dry treatment makes it possible to perform selective cleaning treatment to high-density films, which have been intentionally formed on a substrate and have desired structures, and impurities and unnecessary low-density films such as natural oxide films. For example, a vapor-phase etching or cleaning process for a substrate, which permits controlled removal of films or layers treated with various reaction gases, is proposed in JP 6-26206 B. As another example, dry treatment is proposed in JP 2-197123 A, in which by treatment with an inert gas, etching of an oxide on a front side of a wafer and that of an oxide on a back side of the wafer are controlled to selectively perform etching at only desired regions of the wafer. As a further example, JP 8-319200 discloses a process in which selectivity of removal to low-density films is increased by alternately introducing a reactive gas and an inert gas into a treatment system.

The above-described dry treatment—which acts selectively to high-density films, which have been formed on a substrate and have desired structures, and impurities and low-density films such as natural oxide films—is accompanied by problems as will be described below.

In JP 6-26206 B and JP 2-197123 A, a reactive gas, such as anhydrous hydrogen fluoride gas, and steam are used as cleaning gas in an attempt to minimize an impairment to high-density films (thermal oxide films). When conditions are imposed to the effect that particular films must not be impaired at all as in the case that high-density films already exist on a substrate and are to be used as oxide films in gate regions, the combined inclusion of steam even at a very low concentration in the cleaning gas allows the steam (i.e., water) to act catalytically and hence, to promote the reaction with the reactive gas, thereby causing an impairment on the necessary thermal oxide films in many instances.

In the process proposed in JP 8-319200 A, on the other hand, the cleaning gas is not accompanied by steam, and unnecessary porous oxide layers are selectively removed without impairing exposed high-density films (dense silicon oxide) formed on a substrate. In this process, an active or reactive gas such as hydrogen fluoride gas and an inert gas such as nitrogen are alternately introduced into a chamber with substrates to be treated are placed so that the selective reactivity of the reactive gas to the substrates is increased. According to this process, selective reactivity can be increased to certain extent but on the other hand, there is a high potential problem that subsequent to the removal of the porous oxide layers, water may remain as a reaction product in the substrates or the chamber without being fully exhausted.

The process of JP 8-319200 A is, therefore, not suited in a case that films to be removed are very small and no substantial selectivity to the films to be removed is expected as in the case of thermal oxide films (high-density films) and natural oxide films or chemical oxide films (low-density films), although this process is suited, for example, when upon forming element structures, no difference in selectively is desired between sacrificial oxide films and substrate oxide films or stopper films of silicon nitride or the like capable of withstanding dissolution by chemical solutions are arranged in advance or when a significant difference in selectivity can be expected beforehand between necessary high-density films and unnecessary low-density films from their physical properties. In essence, the above process is not suited where no marked difference in selectivity is expected between necessary high-density films and unnecessary low-density films. The advance arrangement of stopper films may be considered to be an effective measure for wet treatment. However, the arrangement of such stopper films correspondingly requires an additional space, and is disadvantageous for the size reduction of the device.

JP 8-319200A also discloses that upon selective removal of porous oxide layers, water vapor formed as a result of etching with anhydrous hydrogen fluoride gas is exhausted by purging it with an inert gas such as heated nitrogen gas. According to this process, however, an active gas such as anhydrous hydrogen fluoride gas and an inert gas such as nitrogen gas are alternately introduced so that the treatment time obviously becomes longer. There is also a high possibility that, before water as a reaction product has not been fully eliminated, the process may enter a step in which the next etching reaction is induced. In this case, high-density films are impaired. Moreover, the process disclosed in this patent publication is not intended to remove natural oxide films before the formation of gate structures although it is used upon formation of intricate element structures in a substrate.

### SUMMARY OF THE INVENTION

An object of the present invention is, therefore, to provide a cleaning process for a substrate surface, especially a cleaning process for a surface of a substrate suitable for use in a semiconductor device, which can selectively remove only a low-density film (i.e., an unintentionally formed, unnecessary film) without impairing an already formed, high-density film (i.e., an intentionally formed, necessary film), is industrially useful, and can achieve both a reduction in the time of treatment to the substrate surface and significant improvements in the results of the treatment.

Another object of the present invention is to provide a cleaning process for a substrate surface, especially a cleaning process for a surface of a substrate suitable for use in a semiconductor device, which is free of the problem of waste water treatment and the wettability problem of chemical solutions, both of said problems arising in wet treatment, and can be flexibly applied even when a need arises in the future for the treatment of still smaller devices.

A further object of the present invention is to provide a cleaning process for a substrate surface, especially a cleaning process for a surface of a substrate suitable for use in a semiconductor device, which can further promote the move of cleaning treatment toward dry cleaning treatment and can also readily remove, for example, impurities existing on an outermost surface of a silicon substrate and also impurities existing at various depths in the silicon substrate.

A still further object of the present invention is to provide a cleaning process for a surface of a substrate suitable for use in a semiconductor device, which can selectively remove a low-density film, which has been formed in each forming step, by etching without impairing a high-density film in a semiconductor device substrate or the like, can significantly lessen a reduction in the yield of device products, said reduction being attributable to films the removal of which has heretofore been impossible despite the desire, and is useful in industrial fabrication.

The above-described objects can be achieved by the present invention to be described hereinafter. Namely, the present invention provides a process for cleaning a surface of a substrate, said surface carrying thereon a high-density film and a low-density film lower in density than the high-density film in combination, which comprises bringing a mixed gas of anhydrous hydrogen fluoride gas and a heated inert gas into contact with the surface of the substrate such that at least a portion of the low-density film is removed without impairing the high-density film beyond a tolerance.

According to the cleaning process of the present invention, it is possible to conduct cleaning treatment such that a desired structure can be formed by selectively removing only an unnecessary film without impairing an already formed, necessary oxide film or the like. This can achieve a reduction in treatment time and also significant improvements in a substrate after the treatment.

For the removal of impurities on an outermost surface of a substrate, it has been the conventional practice to use thick chemical solutions of high temperature in large volumes. These chemical solutions must be rinsed subsequent to use, thereby developing a problem of waste water treatment. The cleaning process of the present invention makes it possible to treat a substrate surface without using such chemical solutions or, even when chemical solutions are used, without needing paying attention to the characteristic wettability. As a consequence, the cleaning process of the present invention can be flexibly applied even when a need arises in the future for the treatment of still smaller devices.

Further, the cleaning process of the present invention can further promote the move toward dry treatment. For example, impurities which exist on an outermost surface of a silicon substrate and are unnecessary for the formation of elements can also be removed together with a chemical oxide film by conducting oxidization treatment with ozone water or ozone gas in advance to form the chemical oxide film while having the impurities incorporated in the chemical oxide film and then by conducting treatment with anhydrous hydrogen fluoride gas which contains an inert gas heated to room temperature or higher. By repeating this treatment a plurality of times, the cleaning process can also be applied to remove impurities contained at various depths.

Moreover, the cleaning process of the present invention can remove an undesired film, which has been formed in the fabrication process of a device, by excellent selective etching without impairing desired structure and film both of which are needed. Accordingly, the cleaning process of the present invention can bring about a significant contribution to the lessening of a reduction in the yield of device products, said reduction being attributable to films the removal of which has heretofore been impossible despite the desire, and is industrially useful.

### BRIEF DESCRIPTION OF THE DRAWINGS

FIG. 1 is a schematic illustration of a system for practicing a cleaning process of the present invention for a substrate surface; and

FIG. 2 is a diagram showing selectivity of etching to a thermal oxide film and a TEOS film.

### DETAILED DESCRIPTION OF THE INVENTION AND PREFERRED EMBODIMENTS

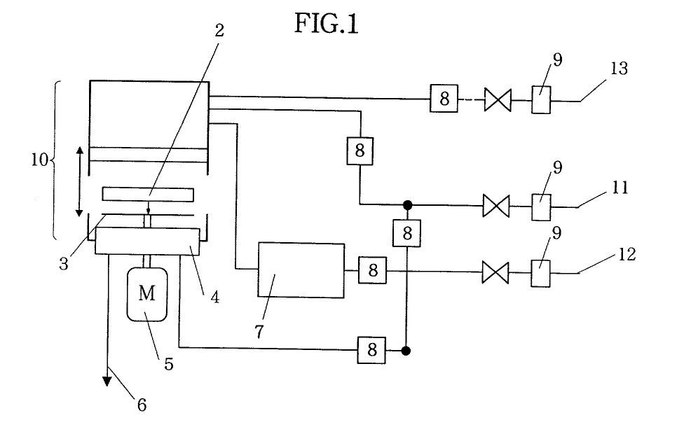

The present invention will hereinafter be described based on preferred embodiments. As the present invention is suitably applicable to silicon substrates, cleaning processes as applied to silicon substrates will hereinafter be described as representative examples, although substrates to which the present invention can be applied are not limited to silicon substrates. The cleaning process of the present invention for a substrate surface is an effective process, which by using such a system as illustrated in FIG. 1, can selectively remove an oxide film of a relatively low density, which exists together with an oxide film of a density higher than the low-density oxide film on a substrate under treatment, without a substantial impairment to the high-density oxide film.

With reference to FIG. 1, a description will first be made of a system which can practice the cleaning process of the present invention for a substrate surface. In the drawing, numeral 3 indicates a vacuum chuck and numeral 2 indicates a substrate, for example, a silicon wafer arranged horizontally on the vacuum chuck for treatment within a chamber 10. The substrate 2 to be treated can be rotated at a high speed by a spin motor 5 arranged underneath the chamber 10. The system is constructed such that into the chamber 10, anhydrous hydrogen fluoride gas 11 as an active gas and an inert as 12 such as nitrogen gas can be introduced through a filter 9 to effect dry treatment of a surface of the substrate while being adequately controlled by corresponding mass-flow controllers 8. As is depicted in FIG. 1, a heater 7 is arranged on a feed line of the inert gas 12 such that the inert gas 12 can be introduced into the chamber 10 after heating it to a desired temperature. The system may also be designed to permit introduction of steam into the chamber 10 as needed, although this feature is not shown in the drawing. The system illustrated in FIG. 1 is constructed such that subsequent to the above-described treatment with the mixed gas, rinsing water 13 is introduced into the chamber 10 through a filter 9 to wash the substrate surface with water. After the water washing, the substrate is rotated at a high speed by the spin motor 5 so that the substrate surface is dried. Subsequent to the washing, the rinsing water is caught in a rinse cup 4 and is then discharged to the outside through a chamber drain 6 extending downwardly from the rinse cup 4.

According to an investigation by the present inventors, it has been found that a low-density oxide film, which exists together with a film of a relatively high density (high-density oxide film) on a substrate to be treated, can be selectively removed without a substantial impairment to the high-density oxide film by using such a system as described above and also employing a mixed gas of anhydrous hydrogen fluoride gas as an etching gas and an inert gas, for example, nitrogen gas heated to room temperature or higher. The cleaning process of the present invention for a substrate surface is effective especially when there is a need for the removal of at least one of unintentionally formed, low-density films (undesired films on element structures, such as natural oxide films and sacrificial oxide films) from the substrate which carries thereon an intentionally formed, high-density film an impairment to which is desired to be avoided as much as possible.

The natural oxide film (low-density oxide film) is lower in density than the thermal oxide film (high-density oxide film) which makes up a gate region, and the natural oxide film has a water content higher than the thermal oxide film. The natural oxide film is, therefore, readily removed with anhydrous hydrogen fluoride gas which is free of water. There is also a difference in the initiating time of the reaction. The natural oxide film reacts earlier than the thermal oxide film, so that the selectivity of removal to the natural oxide film can be fully increased to an extreme provided that the content of water, which catalytically acts in this reaction, can be controlled as desired. The present invention, therefore, makes use of a mixed gas—which contains, in addition to anhydrous hydrogen fluoride gas, nitrogen gas heated to room temperature or higher—as treatment gas when ultimate selectivity to the removal of various films is required. In the present invention, however, the addition of steam which catalytically acts is optional, and treatment of a substrate can be conducted by supplying steam into the mixed gas as needed.

The selective film removal that only an unnecessary film is removed while leaving behind a necessary film without an impairment as in the above-described case of the natural oxide film and the thermal oxide film can be realized for the first time by mixing and contacting an inert gas, which has been heated to room temperature or higher by heating means such as a heater, with anhydrous hydrogen fluoride gas as a reaction gas. Any inert gas can be used in the present invention, but use of nitrogen gas is preferred. As a method for mixing the inert gas with anhydrous hydrogen fluoride gas, anhydrous hydrogen fluoride gas as a reaction gas and the inert gas which has been heated to room temperature or higher may be fed after mixing them beforehand, or these gases may be fed into the chamber through different lines and may then be mixed together in the chamber.

When treating a substrate with the mixed gas of anhydrous hydrogen fluoride gas and the inert gas, it is preferred to raise the surface temperature of the substrate in advance such that the treatment can be conducted under good conditions. The temperature of the chamber should not be lowered beyond necessity. From the standpoint of promptly raising the substrate temperature, it is also desired to maintain the chamber at a temperature equal to or higher than the temperature of the heated gas (the inert gas). By appropriately feeding anhydrous hydrogen fluoride gas under these conditions, unnecessary films such as natural oxide films can be removed before necessary thermal oxide films would be impaired.

As processes for removing unnecessary films from the surface of a silicon substrate or the like, two types of removing processes, that is, wet removing processes and dry removing processes are known as mentioned above. Dry treatment such as the process of the present invention has an advantage in that owing to the use of gases, the concentration of hydrogen fluoride, the temperature of the whole mixed gas, and the like can be easily and precisely controlled by mechanical means such as master-flow controllers. Compared with wet treatment, which makes use of a chemical solution with hydrogen fluoride contained therein, dry treatment is far easier in controlling the treatment conditions. Dry treatment, therefore, makes it possible to perform good treatment even when no marked difference is expected in the selectivity of removal between necessary films (high-density films) and unnecessary films (low-density films).

For example, when wet treatment is applied, no substantial difference is observed in selectivity between films having low density relative to other films and thermal oxide films and films having high density relative to other films, among natural oxide films and oxide films formed by CVD (chemical vapor deposition), irrespective of the kind or state of a chemical solution. According to the cleaning process of the present invention for a substrate surface, on the other hand, selective removing treatment can be applied to the above-described individual films by using a mixed gas of hydrogen fluoride at an appropriate concentration and a suitable inert gas heated to room temperature or higher.

As the inert gas heated to room temperature or higher for use in the present invention, it is preferred to use nitrogen gas of a temperature sufficient to heat the substrate surface to a temperature in a range of from room temperature to 100° C., preferably from 30° C. to 50° C. To this end, it is preferred to control the mixed gas for dry treatment between room temperature and 200° C., preferably between room temperature and 100° C. such that the surface temperature of the substrate can be maintained between room temperature to 100° C., preferably between 30° C. and 50° C. Specifically, it is preferred to use as the inert gas an inert gas heated to a temperature in a range of from 50° C. to 100° C., notably to 65° C. or so. As a feeding rate of nitrogen gas heated to such a temperature into the chamber, 40 to 100 L/min, especially 40 to 60 L/min or so is preferred although the preferred feeding rate varies depending on the capacity of the chamber. The use of a mixed gas, which consists of anhydrous hydrogen fluoride at an appropriate concentration and an inert gas heated as described above, makes it possible to perform selective removal of low-density oxide films from a substrate and as a result, to easily control the surface of the substrate to a desired state.

A description will next be made about selective removal of films, which as described above, has become feasible by dry treatment making use of a mixed gas of anhydrous hydrogen fluoride gas and inert gas heated to room temperature or higher. An oxide film varies in the amount of water contained therein depending on how it is formed, because the water content of an oxide film is primarily determined depending on whether silicon oxide making up the oxide film is dense or non-dense. A non-dense film, in other words, a low-density film is porous so that it adsorbs more water molecules, which naturally exist in air, than a film (high-density film) denser than the low-density film. As a consequence, a difference arises such that the content of water in a film varies depending on whether the film is a high-density film or a low-density film. The cleaning process of the present invention is, therefore, very advantageous for treating a substrate having element structures, which require selectivity, or a substrate in such a state as forming structures, like capacitors, themselves.

As has been described above, it has been found that as an inert gas such as nitrogen heated to room temperature or higher for use in the present invention, one having a temperature capable of heating a substrate surface to 30° C. to 50° C. is preferred. As reasons for this, the present inventors consider as will be described hereinafter. Because water catalytically acts in dry treatment as mentioned above, use of only water adsorbed in a film or on a surface of the film can readily induce an etching reaction with an hydrous hydrogen fluoride gas. Here, the etching reaction proceeds especially in low-density films having higher water content among oxide films existing together on the substrate. As a result of the reaction between the low-density oxide films and hydrogen fluoride, SiF₄ or an equivalent volatile silicon fluoride is formed. At the same time, however, water is also formed as indicated by the following formula (1):

SiO₂+4HF→SiF₄+2H₂O (1)

The above-described formula shows one of representative reactions which take place in this system. The above formula, therefore, does not represent this system in its entirety, and the present invention shall not be limited at all by the above formula.

According to the above formula (1), the resulting water catalytically acts in the reaction system and, as the reaction proceeds, in other words, as time goes on, the reaction is accelerated and may eventually dissolve even desired oxide films of relatively high density existing on a substrate and required structurally. Accordingly, water formed by the reaction must be eliminated promptly from at least element structures. As an effective measure for this purpose, the present invention uses nitrogen gas, which has been heated to room temperature or higher, along with anhydrous hydrogen fluoride gas as mentioned above, whereby water formed by the reaction is dried off. As a consequence, unnecessary low-density films can be removed with high selectivity from a substrate surface, on which the low-density films exist together with high-density films having higher density than the low-density films, without impairing the necessary high-density films.

As the temperature of an inert gas such as nitrogen, which is to be mixed with hydrogen fluoride gas as an active gas, gives considerable influence to the performance of the treatment, it is preferred to keep its feed line warm with a heat-insulating material or the like. This can further improve the process controllability. The feed line for anhydrous hydrogen fluoride gas, on the other hand, may desirably be heated at least to a temperature above its vaporization temperature, preferably to 30° C. or higher to avoid liquefaction of hydrogen fluoride gas.

JP 8-319200 A, which was referred to in the above, discloses to increase the selectivity of treatment by alternately introducing a reactive gas and an inert gas into a treatment system. As a result of an investigation by the present inventors, however, this method has been found to have difficulty in preventing gate thermal oxide films from being impaired, although it can efficiently remove undesired films on element structures such as natural oxide films and sacrificial oxide films. For example, it has been found that under a situation in which gate thermal oxide films supposed to remain free from an impairment exist, a loss of each gate of 10 nm (100 Å) or so can hardly be kept below 0.5 nm (5 Å), the upper limit of the loss.

This means that the above-described conventional process is effective where removal of only undesired unnecessary films from a substrate surface is intended but is very difficult to perform selective removal of only unnecessary films without causing a loss of element structures beyond a tolerance under such a situation that gate thermal oxide films supposed to remain free of an impairment already exist on the substrate surface. Described specifically, according the above-described conventional process, there is a high possibility that subsequent to removal of unnecessary oxide films, water as a reaction product of the removal may remain in the substrate or chamber without sufficient elimination. Such water catalytically acts, and as a result, desired element structures which are needed may be lost in part. According to the cleaning process of the present invention, on the other hand, the conventional problem is avoided by continuously feeding an inert gas, such as nitrogen, heated to room temperature or higher along with anhydrous hydrogen fluoride gas as an active gas until completion of the treatment of a substrate instead of alternately introducing the reactive gas and the inert gas into the treatment system as in the above-described conventional process and by removing undesired films, such as natural oxide films and sacrificial oxide films, on element structures by etching with anhydrous hydrogen fluoride gas while eliminating water, which is formed upon removal, with the inert gas, such as nitrogen, heated to room temperature or higher.

JP 8-319200 A, which was referred to in the above, discloses to remove extra water by using a heated inert gas and to selectively remove unnecessary films without making combined use of steam. According to the conventional technique, however, the inert gas is intermittently introduced into the chamber as mentioned above. The reaction which was once initiated is terminated whenever the introduction of the active gas is stopped, and is resumed by re-introduction of the active gas. The treatment time hence becomes longer unavoidably. The present invention has also brought about a marked improvement in this respect and makes it possible to achieve a significant reduction in the treatment time. Therefore, the cleaning process of the present invention is economical and is very useful industrially.

The cleaning process of the present invention can be used when forming an intricate semiconductor device structure in a substrate, and is also effective for the removal of natural oxide films prior to formation of gate regions. It is also effective for the removal of natural oxide films before formation of gates in memory regions when gate regions (SiO₂) of logic sections already exist in the fabrication of a system LSI. Further, it can be used for removing residues (impurities) at narrow areas in a semiconductor device structure, for example, at locations high in aspect ratio than other locations—such as peripheries and bottoms of trench regions, vias and contacts—and also for removing undesired oxide films.

In addition, it is also effective to apply the cleaning process of the present invention after thermal oxidization is conducted beforehand to form sacrificial oxide films on side walls and bottoms of trenches in a step of removing residues formed by dry etching, for example, upon forming in trench structures such structures as forming gate oxide films. As this application makes it possible to allow residues, i.e., impurities on or in low-density films, the impurities can be selectively removed along with the low-density films.

The cleaning process of the present invention also makes it possible to conduct a modification of a substrate surface. According to an investigation by the present inventors, it has been found that, when treatment is conducted with a mixed gas of active anhydrous hydrogen fluoride gas and an inert gas heated to room temperature or higher, the value of a contact angle of a substrate becomes typically high after the treatment. This means that the property of the substrate surface has changed from a hydrophilic surface to a hydrophobic surface by the cleaning process of the present invention. This change can, therefore, be considered to be one example which illustrates effects of a surface modification. The cleaning process of the present invention is also suitable when a certain small modification is desired in the vicinity of a surface of a substrate under treatment, said modification being required because the cleaning process of the present invention is dry treatment.

It has also been widely reported that a resulting residue varies depending on the kind of a gas to be used in dry etching and that a non-dense SiO₂ film may be formed, for example, when a silicon substrate is subjected to dry etching with a bromine-containing gas. Accordingly, combined use of a dry etching process, which uses the bromine-containing gas, and the cleaning process of the present invention by relying upon the above report makes it possible to readily provide a still cleaner substrate surface without impairing element structures while removing impurities on an outermost suffice.

The present invention will hereinafter be described more specifically based on preferred examples and comparative examples. It is however to be noted that the following examples are merely illustrative and that the present invention is by no means limited by these examples.

As samples to be treated, substrates in each of which two types of surface conditions existed together (hereinafter simply called “wafers”) were provided. Described specifically, employed were wafers (bear/oxide film wafers) each of which was provided on a surface thereof with both a thermal oxide film and a bear silicon surface by stripping off a half of a thermal oxide film with a hydrofluoric acid solution from the wafer the surface of which was fully covered with the thermal oxide film. The bear/oxide film wafers were prepared as will be described below. Firstly, a solution which had been prepared by diluting 50-fold a commercial hydrofluoric acid stock was placed in a simple structure chemical tank which was provided with a TEFLON lining. The wafers which were fully covered at the surfaces thereof with the thermal oxide films, respectively, were held in a wafer cassette with their orientation corners or notches registered, and the cassette was arranged in the chemical tank such that a half of the surface of each wafer was dipped in the chemical solution. After dipped for approx. 30 minutes, the wafers were transferred along with a carrier into a rinsing tank provided in advance, and were washed for 30 minutes with running purified water to remove the chemical solution. The wafers from which the chemical solutions had been rinsed off as mentioned above were spin-dried.

The wafers, each of which had been obtained as described above and had the two types of surface conditions in combination, were equally treated with a sulfuric acid-hydrogen peroxide mixture (a mixed solution of water, hydrogen peroxide and sulfuric acid; will hereinafter be called “SPM”) under the following conditions: 5 minutes, 120° C., water/hydrogen peroxide/sulfuric acid=8:1:1. By that treatment, chemical oxide films were formed on the surfaces of the wafers as oxide films undesired for device structures. A chemical oxide film formed by treatment with a chemical solution such as SPM is an oxide film of approx. 1 nm (10 Å) in thickness, and a wafer surface with such an oxide film formed thereon exhibits typical hydrophilicity. By a contact angle meter [“FACE/Contact Angle Meter (Image Processing Type), Model: CA-X200”, trade name; manufactured by KYOWA INTERFACE SCIENCE CO., LTD.], the chemical oxide films formed by the above-described treatment were confirmed as to whether they were complete or not. Their film thickness values were also determined by an ellipsometer (manufactured by Gaertner Scientific Corporation). As a result, it was confirmed that a chemical oxide film was completely formed on the substrate of each treated sample.

The effectiveness of the present invention was evaluated by checking whether or not the chemical oxide film on each substrate surface was removed by the cleaning process of the present invention without the already-existing thermal oxide film. Described specifically, the thermal oxide film had a thickness of 500 nm (5,000 Å) or so. The thickness of the thermal oxide film before the treatment was measured using a thickness meter (“Nanometric/Nanospec AFT210”, trade name; manufactured by Olympus Optical Co., Ltd.). After removal of the chemical oxide film, the thickness of the thermal oxide film was measured again to determine a loss (Δ) of the thermal oxide film in the course of the treatment. The effectiveness of the present invention was evaluated based on the value of the loss (Δ).

In the above-described evaluation, the wafers with the chemical oxide films formed thereon were treated in an anhydrous hydrogen fluoride vapor treatment system [“EXCALIBUR” (trademark) ISR; manufactured by FSI International, Inc.] by changing its gaseous atmosphere in various ways. The treatment system had such a closed structure as illustrated in FIG. 1, was made of polyvinylidene fluoride (PVDF), and was suited for the practice of the cleaning process of the present invention. As anhydrous hydrogen fluoride gas, one of 99.9% purity was used.

### EXAMPLE 1

In this Example, anhydrous hydrogen fluoride and heated nitrogen were both fed upon treating each substrate surface in the above-described anhydrous hydrogen fluoride treatment system.

Each wafer provided for the treatment carried the chemical oxide film formed by the SPM treatment as described above. In the treatment of the wafer surface in this Example, the wafer was treated for 10 seconds in the above-described anhydrous hydrogen fluoride treatment system. As a gaseous atmosphere at that time, anhydrous hydrogen fluoride gas and heated nitrogen were introduced at flow rates of 1,000 mL/min and 60 L/min, respectively, without introducing absolutely no steam into the treatment chamber. As steam was not introduced in this Example, the reaction was slower than that in the below-described Comparative Example 1 in which steam was introduced, so that the treatment time was longer compared with Comparative Example 1. In this Example, anhydrous hydrogen fluoride gas was carried by nitrogen gas. Further, nitrogen gas was heated to 65° C. by a heater before its introduction into the treatment chamber. Moreover, the chamber into which the heated nitrogen gas was introduced was heated beforehand to 45° C. by a chamber heater which the chamber was equipped with. In addition, the wafer was heated for 10 seconds or so before conducting the treatment.

The wafer treated by the above-described procedures was evaluated in terms of a loss (Δ) of the thermal oxide film by the above-described method. The results are presented in Table 1. Incidentally, the measurement was conducted at different five points on the wafer surface. As a result, the loss of the thermal oxide film was found to be limited below about 0.1 nm (1 Å) as presented in Table 1. This indicates that etching proceeded without impairing the thermal oxide film, in other words, this means that selective film removal was effected. The tolerance of a loss of a thermal oxide film differs depending on the structure and fabrication steps of a device. For example, a thermal oxide film is often used as a gate oxide film in many instances. The extent of a loss can be considered to be acceptable if the loss is about 0.1 nm (1 Å) or less in the case of a thermal oxide film of 10 nm (100 Å). The above-described results are, therefore, considered to be good in view of the fact that the treatment was applied to the films which were not substantially different in selectivity and were small in thickness. The above results also indicate that, even in a step in which a large loss tolerance may be permissible, use of the process of this Example can form a necessary, desired structure with a smaller loss than the conventional process.

TABLE 1
Loss of Thermal Oxide Film When Heated
Mixed Gas Was Introduced (unit: nm)

| Measuring point | 1 | 2 | 3 | 4 | 5 |
|---|---|---|---|---|---|
| Before treatment | 452.0 | 432.7 | 435.0 | 442.3 | 443.2 |
| After treatment | 451.9 | 432.5 | 434.9 | 442.3 | 443.1 |
| Loss (Δ) | 0.1 | 0.2 | 0.1 | 0 | 0.1 |

Further, to confirm the existence of a chemical oxide film on the surface of the substrate wafer employed as the sample to be treated, the contact angle was measured at three points on a bear silicone wafer and also in the bear silicon area of the bear/oxide film wafer. The results are presented in Table 2. As is appreciated from Table 2, a chemical oxide film was fully formed on the surface of the wafer substrate.

TABLE 2
Contact Angle (°) in Bear Silicon Area
When Heated Mixed Gas Was Introduced

| Measuring point | 1 | 2 | 3 | Average |
|---|---|---|---|---|
| Before treatment | 0 | 0 | 0 | 0.0 |
| After treatment | 49.5 | 48.6 | 47.2 | 48.4 |

With respect to the chemical oxide film existing on the wafer surface and confirmed as described above, its conditions were measured by an ellipsometer both before and after the treatment. The results are presented in Table 3. As is appreciated from Table 3, it has been confirmed from the actually measured thickness of the chemical oxide film that the chemical oxide film formed beforehand on the wafer had been removed by the treatment of this Example. Incidentally, with the ellipsometer employed in this Example, thickness values of 0.4 nm (4 Å) and smaller do not have much significance in view of the accuracy of the instrument. It is therefore reasonable to interpret values smaller than 0.4 nm such that the chemical oxide film had been removed to below the detection limit. Also taking into consideration that the loss of the thermal oxide film by the treatment was limited to 0.1 nm (1 Å) or smaller according to the treatment of this Example as indicated in Table 1, it is understood that the feeding of heated nitrogen along with anhydrous hydrogen fluoride gas was able to eliminate water, which occurred in the course of the etching reaction of the chemical oxide film with anhydrous hydrogen fluoride gas, together with water, which had been adsorbed on the surface of the substrate, to certain extent. Further, the process of this Example does not require suspension of the reaction unlike Comparative Example 3 to be described subsequently herein, and therefore, is very useful in that the time required for the treatment is short and also in that only undesired oxide films can be continuously removed with good selectivity without impairing necessary oxide films.

TABLE 3
Changes in Thickness of Chemical Oxide Film When
Heated Mixed Gas Was Introduced (unit: nm)

| Measuring point | 1 | 2 | 3 |
|---|---|---|---|
| Before treatment | 0.709 | 0.822 | 0.826 |
| After treatment | 0.273 | 0.386 | 0.404 |
| Loss (Δ) | 0.436 | 0.436 | 0.422 |

### EXAMPLE 2

Selective etching upon formation of structures was investigated in this Example.

Using the same system as that employed in Example 1, each substrate surface was treated under similar conditions as in Example 1, and selectivity of removal to a similar thermal oxide film as in Example 1 and that to a TEOS (doped silicon oxide) film formed on a wafer by CVD were confirmed. Provided wafers were separately treated in the anhydrous fluorine hydride gas treatment system. The treatment time was changed to confirm whether or not only the thermal oxide film out of the above-described two types of oxide films would be selectively etched. As in Example 1, absolutely no steam was introduced into the treatment chamber during the treatment, and anhydrous hydrogen fluoride gas and nitrogen heated to 65° C. were introduced at flow rates of 1,000 mL/min and 60 L/min, respectively, during the treatment. The treatment chamber was heated beforehand to 65° C. by the heater which the treatment chamber was equipped with. Further, the treatment was conducted by heating each wafer beforehand for 10 seconds or so. Anhydrous hydrogen fluoride gas was carried by nitrogen gas.

Similarly to Example 1, the treatment time was also longer in this Example than in Comparative Example 1 to be described subsequently herein. Thickness values of the thermal oxide film and TEOS film were also determined at predetermined intervals in the course of the treatment, and are presented in Table 4. As a result, it was confirmed that, as opposite to a loss of 0.4 nm or smaller in the case of the thermal oxide film, the degree of etching of the TEOS film was great, increased with the treatment time, and was selectively removed.

TABLE 4
Losses of Thermal Oxide Film and TEOS Film
When Heated Mixed Gas Was Introduced

| | |
|---|---|
| Treatment time | Degree of etching (nm) |

| (sec.) | Thermal oxide film | TEOS film |
|---|---|---|
| 5 | 0.3 | 1.9 |
| 10 | 0.3 | 2.7 |
| 20 | 0.3 | 5.7 |
| 30 | 0.4 | 11.1 |

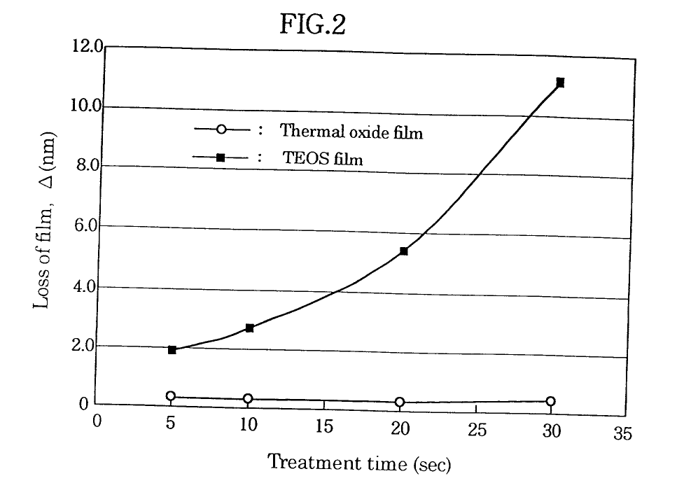

FIG. 2 diagrammatically illustrates, as a function of treatment time, changes in the degree of etching occurred on the thermal oxide film and TEOS film as a result of the above-described treatment. As is readily envisaged from FIG. 2, it is evident that, although the loss of the thermal oxide film remained constant at about 0.3 nm (3 Å), the degree of etching of the TEOS film increased with the treatment time and the selectivity of removal to the TEOS film increased as time went on. It is not difficult to estimate that the selectivity increases further in the case of films doped with B and/or P.

The above results indicate that, under the treatment conditions used in this Example that heated nitrogen gas is introduced along with anhydrous hydrogen fluoride gas as an active gas, only unnecessary TEOS films can be continuously removed with good selectivity without impairing necessary thermal oxide films by allowing the etching reaction to proceed while removing water occurring by the etching reaction of only TEOS oxide films and also eliminating to certain extent water adsorbed on the substrate surface. These features, in turn, indicate that the above-described process can also be used for the formation of element structures such as capacitors or for the selective removal of only some films in fine structures to clean, for example, side walls and bottoms of trenches, contact holes and the like.

### COMPARATIVE EXAMPLE 1

As a comparative example, treatment of substrates was conducted while feeding anhydrous hydrogen fluoride gas and steam together without introducing any heated inert gas. The wafers provided for the treatment were those carrying a chemical oxide film formed by SPM treatment as in Example 1. Those wafers were treated for 4 seconds in a similar anhydrous hydrogen fluoride vapor system as those employed in Examples 1 and 2. As a gaseous atmosphere during the treatment, steam of 25° C. and atmospheric pressure was carried by nitrogen gas. By changing its introduction rate, an investigation was made for two cases of 3 L/min and 8 L/min in total flow rate. Anhydrous hydrogen fluoride gas was introduced at 40 mL/min. Anhydrous hydrogen fluoride gas was also carried by nitrogen gas.

A loss of the oxide film when steam was introduced at 3 L/min is presented in Table 5-1, while a loss of the oxide film when steam was introduced at 8 L/min is shown in Table 5-2.

TABLE 5-1
Loss of Thermal Oxide Film When Steam
Was Introduced at 3L/min (unit: nm)

| Measuring point | 1 | 2 | 3 | 4 | 5 |
|---|---|---|---|---|---|
| Before treatment | 422.7 | 411.5 | 421.3 | 424.9 | 433.8 |
| After treatment | 421.9 | 410.7 | 420.7 | 424.4 | 433.6 |
| Loss (Δ) | 0.8 | 0.8 | 0.6 | 0.5 | 0.2 |

TABLE 5-2
Loss of Thermal Oxide Film When Steam
Was Introduced at 8L/min (unit: nm)

| Measuring point | 1 | 2 | 3 | 4 | 5 |
|---|---|---|---|---|---|
| Before treatment | 440.2 | 411.8 | 393.9 | 411.8 | 443.5 |
| After treatment | 439.0 | 410.8 | 393.0 | 410.9 | 442.6 |
| Loss (Δ) | 1.2 | 1.0 | 0.9 | 0.9 | 0.9 |

As is readily envisaged from the results in Table 5-1 and Table 5-2, it has been found that the loss of a thermal oxide film increases with the amount of introduced steam. Although the tolerance of a loss of a thermal oxide film differs depending on the device or step as mentioned above, a thermal oxide film is widely used, for example, as a gate oxide film or the like in many instances, and the loss is substantial if it reaches 1 nm (10 Å) or so when the thermal oxide film is 10 nm (100 Å) in thickness. It is therefore evident that, for the removal of an oxide film which does not have high selectivity and is small in thickness, the conditions of this Comparative Example are not considered to be optimal and cannot achieve the objects of the present invention. Needless to say, this is not the case when the treatment is used only for stripping which does not require selective removal of films.

To confirm the state of existence of a chemical oxide film after the treatment, the contact angle was measured on a bear silicone wafer and also in the bear silicon area of the bear/oxide film wafer. The results are presented in Tables 6-1 and 6-2. As is appreciated from Tables 6-1 and 6-2, the value of contact angle increased with the amount of introduced steam. In the pre-treatment state in which the chemical oxide film existed, the contact angle was so small that its measurement was not feasible. It is, therefore, indicated that removal of unnecessary chemical oxide films is feasible even when they are treated under the conditions of this Comparative Example. As is evident from Tables 5-1 and 5-2, however, it has been confirmed that under the conditions of this Comparative Example, the prevention of a loss of each necessary thermal oxide film cannot be expected upon removal of chemical oxide films. Under the conditions of this Comparative Example, the treatment time was as short as 4 seconds. This treatment time is a minimum value in a range in which the flow rate of gas is controllable. It is, therefore, theoretically possible to make the loss of a thermal oxide film smaller than the above loss by shortening the treatment time. Nonetheless, the process of this Comparative Example cannot used as a practical process because a problem arises in the reproducibility of the treatment.

TABLE 6-1
Contact Angle (°) in Bear Silicon Area
When Steam Was Introduced at 3 L/min

| Measuring point | 1 | 2 | 3 | Average |
|---|---|---|---|---|
| Before treatment | 0 | 0 | 0 | 0.0 |
| After treatment | 20.7 | 18 | 20.1 | 19.6 |

TABLe 6-2
Contact Angle (°) in Bear Silicon Area
When Steam Was Introduced at 8 L/min

| Measuring point | 1 | 2 | 3 | Average |
|---|---|---|---|---|
| Before treatment | 0 | 0 | 0 | 0.0 |
| After treatment | 24.8 | 20.3 | 23.1 | 22.7 |

### COMPARATIVE EXAMPLE 2

In this Comparative Example, substrates were treated using only anhydrous hydrogen fluoride gas without introducing any heated inert gas. The wafers provided for the treatment were those carrying a chemical oxide film formed by SPM treatment as in Example 1. Those wafers were treated for 10 seconds in a similar anhydrous hydrogen fluoride vapor system as those employed in Examples 1 and 2. As a gaseous atmosphere during the treatment, only anhydrous hydrogen fluoride gas was introduced at a flow rate of 40 mL/min without introducing any steam into the treatment chamber. As steam was not introduced in this Comparative Example, the reaction was slower than that in Comparative Example 1 in which steam was introduced, so that the treatment time was longer compared with Comparative Example 1. Incidentally, anhydrous hydrogen fluoride gas was carried by nitrogen gas.

A loss of the oxide film occurred by the above-described treatment is presented in Table 7. As is clearly envisaged from the results shown in Table 7, it was confirmed that the loss of a thermal oxide film was reduced in this Comparative Example than in Comparative Example 1. Although the tolerance of a loss of a thermal oxide film differs depending on the device or step, a thermal oxide film is widely used, for example, as a gate oxide film or the like in many instances, and a loss may develop a more or less problem even if it is 0.5 nm (5 Å) or so when the thermal oxide film is 10 nm (100 Å) in thickness. It is therefore evident that, for the removal of an oxide film which does not have high selectivity and is small in thickness, the conditions of this Comparative Example are not considered to be optimal and cannot achieve the objects of the present invention. Needless to say, this is not the case when a step in which a large tolerance is permissible with respect to a loss is chosen.

TABLE 7
Loss of Thermal Oxide Film When
No Steam Was Introduced (unit: nm)

| Measuring point | 1 | 2 | 3 | 4 | 5 |
|---|---|---|---|---|---|
| Before treatment | 422.5 | 403.2 | 415.6 | 451.2 | 406.9 |
| After treatment | 422.0 | 402.8 | 415.0 | 450.8 | 406.6 |
| Loss (A) | 0.5 | 0.4 | 0.6 | 0.4 | 0.3 |

To confirm the state of existence of the chemical oxide film on the substrate surface after the treatment under the conditions of this Comparative Example, the contact angle was measured on a bear silicon wafer and in the bear silicon area of the bear/oxide film wafer. The results are presented in Table 8. According to the results, the contact angle was higher in this Comparative Example than in Comparative Example 1 in which steam was introduced. This indicates that the removal of the chemical oxide film was conducted better in this Comparative Example than in Comparative Example 1. This means that, although practically no water existed in the beginning of the treatment under the conditions of this Comparative Example, the removal reaction of the chemical oxide film took place and the etching of the chemical oxide film on the substrate surface hence proceeded while using the water formed as a reaction product in the removal reaction. It is also indicated that the effect of this reaction is dependent on time and treatment over a long time is needed to obtain a still higher contact angle.

TABLE 8
Contact Angle (°) in Bear Silicon Area
When No Steam Was Introduced

| Measuring point | 1 | 2 | 3 | Average |
|---|---|---|---|---|
| Before treatment | 0 | 0 | 0 | 0.0 |
| After treatment | 32.0 | 27.5 | 26.8 | 28.7 |

In the pre-treatment state in which the chemical oxide film existed, the contact angle was so small that its measurement was not feasible as show in Table 8. It has, therefore, been found that removal of unnecessary chemical oxide films is feasible even when they are treated under the conditions of this Comparative Example. As is evident from Table 7, however, it has been confirmed that under the conditions of this Comparative Example, the prevention of a loss of each necessary thermal oxide film cannot be expected. It is theoretically possible to reduce the loss further by making the treatment time shorter. This approach, however, is not expected to become a very effective measure insofar as the water as a reaction product remains.

### COMPARATIVE EXAMPLE 3

In this Comparative Example, treatment of substrates was conducted in a state such that anhydrous hydrogen fluoride gas and nitrogen were alternately introduced into a chamber. The wafers provided for the treatment were those carrying a chemical oxide film formed by SPM treatment as in Example 1. Those wafers were treated in a similar anhydrous hydrogen fluoride vapor system as those employed in Examples 1 and 2. During the treatment, the treatment with anhydrous hydrogen fluoride gas was conducted for 5 seconds, the introduction of anhydrous hydrogen fluoride gas was stopped, and then, purging with nitrogen was conducted for 5 seconds. As a single set of procedures, those procedures were conduced twice, so that the treatment was conducted for 20 second in total. During the treatment, steam was not introduced at all into the treatment chamber, and only anhydrous hydrogen fluoride gas was introduced at 40 mL/min. As steam was not introduced in this Comparative Example, the reaction was slower than that in Comparative Example 1, so that the treatment time was longer compared with Comparative Example 1. As anhydrous hydrogen fluoride gas and nitrogen were introduced alternately, a longer treatment time was needed than in Example 1. Incidentally, anhydrous hydrogen fluoride gas was carried by nitrogen gas.

The degree of a loss of the thermal oxide film occurred when treated as described above is presented in Table 9. To confirm the state of existence of the chemical oxide film, the contact angle was measured on a bear silicon wafer and in the bear silicon area of the bear/oxide film wafer. The results are presented in Table 10. Based on the results, it has been confirmed that the loss of the thermal oxide film decreased in Comparative Example 3 than in Comparative Example 1 in which steam was also introduced, that the contact angle was higher in Comparative Example 3 than in Comparative Example 2 in which the treatment was conducted with anhydrous hydrogen fluoride gas alone, and also that the etching of the chemical oxide film proceeded further without impairing the thermal oxide film in Comparative Example 3 than in Comparative Examples 1 and 2. In other words, it can be mentioned that the possibility of selective removal of films was improved in Comparative Example 3 than in Comparative Examples 1 and 2 by the alternate introduction of anhydrous hydrogen fluoride gas and nitrogen.

TABLE 9
Loss of Thermal Oxide Film When
No Steam Was Introduced (unit: nm)

| Measuring point | 1 | 2 | 3 | 4 | 5 |
|---|---|---|---|---|---|
| Before treatment | 400.4 | 398.8 | 405.0 | 412.2 | 399.6 |
| After treatment | 400.1 | 398.5 | 404.6 | 411.9 | 399.4 |
| Loss (Δ) | 0.3 | 0.3 | 0.4 | 0.3 | 0.2 |

TABLE 10
Contact Angle (°) in Bear Silicon Area
When No Steam Was Introduced

| Measuring point | 1 | 2 | 3 | Average |
|---|---|---|---|---|
| Before treatment | 0 | 0 | 0 | 0.0 |
| After treatment | 30.8 | 33.6 | 32.6 | 32.3 |

Although the tolerance of a loss differs depending on the device or step, a thermal oxide film is widely used, for example, as a gate oxide film or the like in many instances, and a loss may be considered to be acceptable if it is 1 nm (10 Å) or so when the thermal oxide film is 10 nm (100 Å) in thickness. Nonetheless, the loss in this Comparative Example was not considered to be sufficient when compared with the loss in Example 1. It has, therefore, been found that the conditions used in this Comparative Example are not considered to be optimal for the removal of an oxide film which does not have high selectivity and is small in thickness. This is however not always the case, and the conditions of this Comparative Example are still sufficient for the treatment in a step in which a large tolerance is permissible with respect to a loss.

As has been described above, the contact angle was greater in Comparative Example 3 than in Comparative Example in which steam was introduced. This indicates that the removal of the chemical oxide film was conducted better in this Comparative Example than in Comparative Example 1. This means that, although practically no water existed in the beginning of the treatment under the conditions of this Comparative Example, the removal reaction of the chemical oxide film took place and the etching of the chemical oxide film on the substrate surface hence proceeded while using the water formed as a reaction product in the removal reaction. Under the conditions of this Comparative Example, the formation of water as a reaction product can be stopped by switching to nitrogen gas in the course of the reaction and terminating the reaction with anhydrous hydrogen fluoride gas as an active gas, and further, water can be eliminated by nitrogen gas. Compared with the continuous introduction of anhydrous hydrogen fluoride gas in Comparative Example 2, the reduction in the loss of the thermal oxide film and the degree of removal of the chemical oxide film were improved although the improvements were not large. It has, however, been found that under the conditions of this Comparative Example, complete removal of water formed on the surface is difficult basically and the degree of selective removal of the film is inferior to those achieved in the Examples. Further, compared with Example 1, Comparative Example 3 requires considerably longer dipping time and is also inferior in economy.

1. A process for cleaning a surface of a substrate, said surface carrying thereon a high-density film and a low-density film lower in density than said high-density film in combination, which comprises bringing a mixed gas of anhydrous hydrogen fluoride gas and a heated inert gas into contact with said surface of said substrate such that at least a portion of said low-density film is removed without impairing said high-density film beyond a tolerance.

2. A process according to claim 1, wherein said high-density film is a film necessary for said substrate and said low-density film is a film unnecessary for said substrate.

3. A process according to claim 1, wherein said low-density film includes impurities thereon or therein, and said impurities are removed together with said low-density film.

4. A process according to claim 1, wherein said mixed gas further comprises steam added therein.

5. A process according to claim 1, wherein said substrate is a silicon substrate, said high-density film is a thermal oxide film, and said low-density film is a natural oxide film formed on said surface of said substrate or an oxide film formed with a chemical solution on said surface of said substrate.

6. A process according to claim 1, wherein said substrate is a substrate for a semiconductor device.

7. A process according to claim 6, wherein said high-density film is formed on said substrate via a substrate layer.

8. A process according to claim 1, wherein said mixed gas is maintained at a temperature between room temperature and 200° C.

9. A process according to claim 1, wherein said mixed gas is maintained at a temperature between room temperature and 100° C.

10. A process according to claim 1, wherein said surface of said substrate is maintained at a temperature between 30° C. to 50° C.

11. A process according to claim 1, wherein said mixed gas has a flow rate of from 40 to 60 L/min.

12. A process according to claim 1, wherein a concentration of anhydrous hydrogen fluoride gas contained in said mixed gas is in a range of from 1 vol. % to 3 vol. %.

13. A process according to claim 1, wherein a concentration of anhydrous hydrogen fluoride gas contained in said mixed gas is in a range of from 1.5 vol. % to 2 vol. %.
